(19) United States
(12) Patent Application Publication
(10) Pub. No.: US 2026/0301799 A1
(43) Pub. Date: Oct. 1, 2026

(54) DATA READ-WRITE CIRCUIT AND METHOD THEREFOR, MEMORY AND DRIVING METHOD THEREFOR, AND ELECTRONIC DEVICE

(71) Applicant: BEIJING SUPERSTRING ACADEMY OF MEMORY TECHNOLOGY, Beijing (CN)

(72) Inventors: Zhengyong ZHU, Beijing (CN); Bok Moon KANG, Beijing (CN); Chao ZHAO, Beijing (CN)

(21) Appl. No.: 19/475,984

(22) PCT Filed: Oct. 26, 2023
(86) PCT No.: PCT/CN2023/126730

§ 371 Date: Oct. 16, 2025

(30) Foreign Application Priority Data
Apr. 28, 2023 (CN) 202310479255.X

(51) Int. Cl. G11C 11/4096; G11C 11/4091; G11C 11/4094

(52) U.S. Cl. CPC G11C 11/4096; G11C 11/4091; G11C 11/4094

(57) ABSTRACT

The present disclosure relates to the technical field of storage, and relates to a data read-write circuit and a method therefor, a memory and a driving method therefor, and an electronic device, used for improving the accuracy of data reading. The data read-write method is applied to a storage unit (U), and comprises the following steps: in a pre-charging phase, a data signal line (BL1) provides a first reference voltage (v1) to a storage transistor (T1), an auxiliary signal line (BL2) simultaneously provides the first reference voltage (v1) to the storage transistor (T1) and a write transistor (T2), and the write transistor (T2) is turned on to pre-charge a storage node (SN) between the write transistor (T2) and the storage transistor (T1), wherein the sum of the maximum data voltage corresponding to data that can be stored by the storage unit (U) and a threshold voltage of the storage transistor (T1) is a reference voltage, and the first reference voltage (v1) is greater than the reference voltage; and in a data writing phase, in response to a write command, the auxiliary signal line (BL2) floats, and the data signal line (BL1) provides a data voltage to the storage transistor (T1), the storage transistor (T1) is turned on, and the storage node (SN) discharges to a stable state to write data corresponding to the data voltage.

### CROSS-REFERENCE TO RELATED APPLICATION(S)

This application claims priority to Chinese Patent Application No. 202310479255.X filed with the China National Intellectual Property Administration on Apr. 28, 2023 and entitled “DATA READ-WRITE CIRCUIT AND METHOD THEREFOR, MEMORY AND DRIVING METHOD THEREFOR, AND ELECTRONIC DEVICE”, the disclosure of which is hereby incorporated by reference in its entirety.

### TECHNICAL FIELD

The present disclosure relates to the field of storage technology, and more particularly to, a data read/write circuit and a method for data read/write, a memory and a method for driving a memory, and an electronic device.

### BACKGROUND

With development of the communication technology and the digital technology, people continuously pursue a product with lower power consumption, a lighter weight and better performance. It is easy for the memory to have a higher integration density and larger storage capacity, which has gradually become one of an important research direction in the current storage field. For example, in a three-dimensional dynamic random access memory (3D DRAM), compared with a memory cell employing the one transistor and one capacitor (1T1C) architecture, a memory cell employing two transistors (2T) architecture can effectively solve the problem of difficult capacitor preparation process caused by the reduction of critical size when the 1TIC architecture is employed for the memory cell.

### SUMMARY

According to some embodiments, an aspect of the present disclosure provides a method for data read/write that is applied to a memory cell. The memory cell is configured to store data and includes a storage transistor and a write transistor that are connected with each other. A data read/write cycle of the memory cell includes: a pre-charging stage and a data writing stage. The method for data read/write includes following operations.

In the pre-charging stage, a data signal line supplies a first reference voltage to the storage transistor; an auxiliary signal line supplies the first reference voltage to both the storage transistor and the write transistor; and the write transistor is turned on to pre-charge a storage node between the write transistor and the storage transistor, where a sum of a maximum data voltage corresponding to data capable of being stored by the memory cell and a threshold voltage of the storage transistor is a reference voltage, and the first reference voltage is greater than the reference voltage.

In the data writing stage, in response to a write command, the auxiliary signal line is floated, and the data signal line supplies a data voltage to the storage transistor. The storage transistor is turned on, and the storage node is discharged to be in a stable state to write the data corresponding to the data voltage.

According to some embodiments, the data read/write cycle further includes: a data retention stage following the data writing stage. The method for data read/write further includes: in the data retention stage, a voltage of the data signal line is pulled up to the first reference voltage, the write transistor is turned off after the voltage of the data signal line is the first reference voltage, and then a voltage of the auxiliary signal line is pulled up to the first reference voltage. In addition, after the write transistor is turned off, the method for data read/write further includes: a first turn-off control voltage is applied to the storage transistor.

According to some embodiments, the data read/write cycle further includes: a data retention stage following the data writing stage. The method for data read/write further includes: in the data retention stage, the storage transistor is firstly turned off and a voltage of the data signal line is pulled up to the first reference voltage; and then the write transistor is turned off and a voltage of the auxiliary signal line is pulled up to the first reference voltage.

According to some embodiments, the data read/write cycle further includes: a data reading stage. The method for data read/write further includes following operation.

In the data reading stage, in response to a read command, a read control voltage is applied to the storage transistor and a second reference voltage is supplied, through the auxiliary signal line, to both the storage transistor and the write transistor; where the data signal line is further configured to read data in response to whether the storage transistor is turned on.

According to some embodiments, data written into the storage node includes “1” or “0”. In the data reading stage, the storage transistor is in a on state when the data stored in the storage node is “1”, and the storage transistor is in an off state when the data stored in the storage node is “0”.

According to some embodiments, the data read/write cycle further includes: a standby stage preceding the pre-charging stage and/or preceding the data reading stage. The method for data read/write further includes following operation.

In the standby stage, the storage transistor and the write transistor are in an off state, the data signal line supplies the first reference voltage to the storage transistor, and the auxiliary signal line supplies the first reference voltage to both the storage transistor and the write transistor.

According to some embodiments, the data read/write cycle further includes: a data retention stage following the data writing stage. The data reading stage is following the data retention stage. The standby stage includes a first standby stage preceding the pre-charging stage, and a second standby stage following the data retention stage and preceding the data reading stage.

According to some embodiments, another aspect of the present disclosure further provides a data read/write circuit including a memory cell, a data signal line, and an auxiliary signal line. The memory cell is configured to store data and includes a storage transistor and a write transistor that are connected with each other. The data signal line is connected to the storage transistor and configured to: supply a first reference voltage to the storage transistor in a standby stage and a pre-charging stage, write data into the storage transistor in a data writing stage, and read data in response to whether the storage transistor is turned on in a data reading stage. The auxiliary signal line is connected to the storage transistor and the write transistor and configured to: supply the first reference voltage to both the storage transistor and the write transistor in the standby stage and the pre-charging stage, be floated in the data writing stage, and supply the second reference voltage to both the storage transistor and the write transistor in the data reading stage. A sum of a maximum data voltage corresponding to data capable being stored by the memory cell and a threshold voltage of the storage transistor is a reference voltage; and the first reference voltage is greater than the reference voltage.

According to some embodiments, the data read/write circuit further includes a first control signal line and a second control signal line. The first control signal line is connected to the storage transistor and configured to: control the storage transistor to be turned off in the standby stage, apply a first write control voltage to the storage transistor in the pre-charging stage and the data writing stage, and apply a read control voltage to the storage transistor in the data reading stage. The second control signal line is connected to the write transistor and configured to: control the write transistor to be turned off in the standby stage and the data reading stage, and control the write transistor to be turned on in the data writing stage.

According to some embodiments, the data signal line is further configured to: supply the first reference voltage to the storage transistor in a data retention stage. The second control signal line is further configured to: control the write transistor to be turned off after a voltage of the data signal line is the first reference voltage in the data retention stage. The auxiliary signal line is further configured to: supply the first reference voltage to both the storage transistor and the write transistor after the write transistor is turned off in the data retention stage. In addition, the first control signal line is further configured to: apply a first turn-off control voltage to the storage transistor after the write transistor is turned off in the data retention stage.

According to some embodiments, the first control signal line is further configured to: control the storage transistor to be turned off earlier than the write transistor in a data retention stage. The data signal line is further configured to: supply the first reference voltage to the storage transistor after the storage transistor is turned off in the data retention stage. The second control signal line is further configured to: control the write transistor to be turned off after the data signal line supplies the first reference voltage in the data retention stage. The auxiliary signal line is further configured to: supply the first reference voltage to both the storage transistor and the write transistor after the write transistor is turned off in the data retention stage.

According to some embodiments, the storage transistor includes a storage gate, a first gate, a first electrode, and a second electrode. The write transistor includes a second gate, a first electrode, and a second electrode. The first gate is connected to the first control signal line. The second gate is connected to the second control signal line. The first electrode of the storage transistor is connected to the data signal line. The first electrode of the write transistor is connected to the storage gate, and an intersection point where the first electrode of the write transistor is connected to the storage gate is a storage node. The second electrode of the storage transistor and the second electrode of the write transistor are respectively connected to the auxiliary signal line.

According to some embodiments, a number of the memory cells is multiple. The multiple the memory cells are arranged in a row in a first direction and arranged in a column in a second direction; and the first direction intersects with the second direction. A column of the memory cells share one data signal line and one auxiliary signal line. A row of the memory cells share one first control signal line and one second control signal line.

According to some embodiments, the data read/write circuit further includes a first reference voltage terminal and a second reference voltage terminal. The first reference voltage terminal is correspondingly connected to the data signal line through a first gating circuit and correspondingly connected to the auxiliary signal line through a second gating circuit. The first reference voltage terminal is configured to supply the first reference voltage. The first gating circuit is configured to: selectively connect the first reference voltage terminal to the data signal line in the standby stage and the pre-charging stage. The second gating circuit is configured to: selectively connect the first reference voltage terminal to the auxiliary signal line in the standby stage and the pre-charging stage. The second reference voltage terminal is correspondingly connected to the auxiliary signal line through a third gating circuit. The second reference voltage terminal is configured to supply the second reference voltage. The third gating circuit is configured to: selectively connect the second reference voltage terminal to the auxiliary signal line in the data reading stage.

According to some embodiments, yet another aspect of the present disclosure further provides a memory including: at least one memory cell, and a first bit line, a second bit line, a first word line, and a second word line that are correspondingly connected to the memory cell; where the memory cell includes: a storage transistor and a write transistor. The storage transistor includes a storage gate, a first gate, a first electrode, and a second electrode. The write transistor includes a second gate, a first electrode, and a second electrode. The storage gate is connected to the first electrode of the write transistor, and an intersection point where the storage gate is connected to the first electrode of the write transistor is a storage node. The first word line is connected to the first gate, and the second word line is connected to the second gate. The first bit line is connected to the first electrode of the storage transistor, and the second bit line is connected to both the second electrode of the storage transistor and the second electrode of the write transistor. The first bit line is configured to: supply a data voltage of data to be written into the storage transistor in a data writing stage, and read data written into the memory node in response to whether the storage transistor is turned on in a data reading stage.

According to some embodiments, still another aspect of the present disclosure further provides a method for driving a memory applied to the aforementioned memory. The method includes following operations.

In a pre-charging stage, the first bit line supplies the first reference voltage to the first electrode of the storage transistor, and the second bit line supplies the first reference voltage to both the second electrode of the storage transistor and the second electrode of the write transistor; the first word line applies a first write control voltage to the first gate, and the second word line applies a second write control voltage to the second gate to control the write transistor to be turned on to pre-charge the storage node.

In a data writing stage, the second bit line is floated and the first bit line supplies a data voltage to the first electrode of the storage transistor; the storage transistor is turned on, the storage node is discharged to be in a stable state to write data corresponding to the data voltage.

In a data reading stage, the second word line applies a second turn-off control voltage to the second gate, the write transistor is in an off state; the first word line applies a read control voltage to the first gate; the second bit line supplies a second reference voltage to both the second electrode of the storage transistor and the second electrode of the write transistor; and the first bit line reads the data written into the storage node in response to whether the storage transistor is turned on. The first reference voltage is greater than a sum of a maximum data voltage to be written into the memory cell and a threshold voltage of the storage transistor.

According to some embodiments, still another aspect of the present disclosure further provides an electronic device including: the data read/write circuit in the aforementioned some embodiments; or the memory in the aforementioned some embodiments.

Details of one or more embodiments of the present disclosure are set forth in the following drawings and description. Other features, objects and advantages of the present disclosure will become apparent from the specification, drawings and claims.

### BRIEF DESCRIPTION OF THE DRAWINGS

In order to explain more clearly technical solutions of the embodiments of the present disclosure, desirable accompanying drawings in the description of the embodiments will be introduced simply below. Obviously, the drawings in the below description are only used for some embodiments of the present disclosure, and other drawings of the embodiments may be acquired based on these drawings by those skilled in the art without creative efforts.

FIG. 1 is a schematic circuit diagram of a memory cell with a 2T0C architecture provided in the related art.

FIG. 2 is a schematic circuit diagram of a memory cell with another 2T0C architecture provided in the related art.

FIG. 3 is a schematic circuit diagram of a data read/write circuit or a memory according to some embodiments of the present disclosure.

FIG. 4 is a structural block diagram of a data read/write circuit or a memory according to some embodiments of the present disclosure.

FIG. 5 is an equivalent circuit diagram of the data read/write circuit or the memory illustrated in FIG. 4.

FIG. 6 is a timing diagram of a method for data read/write or a method for driving a memory according to some embodiments of the present disclosure.

FIG. 7 is a timing diagram of another method for data read/write or another method for driving a memory according to some embodiments of the present disclosure.

FIG. 8 is a timing diagram of yet another method for data read/write or yet another method for driving a memory according to some embodiments of the present disclosure.

FIG. 9 is a graph of a current-voltage characteristic of a storage transistor in a data reading stage according to some embodiments of the present disclosure.

### DETAILED DESCRIPTION

To facilitate the understanding of the present disclosure, the present disclosure will be described more fully below with reference to the related drawings. Embodiments of the present disclosure are illustrated in the drawings. However, the present disclosure may be implemented in many different forms and is not limited to the embodiments described herein. Rather, these embodiments are provided in order to make the disclosure more thorough and comprehensive.

Unless otherwise defined, all technical and scientific terms used herein have the same meaning as commonly understood by those skilled in the technical field of the present disclosure. The terms used in the disclosure is only for the purpose of describing the present disclosure, and is not intended to limit the present disclosure.

The “embodiment” mentioned in the disclosure means that particular features, structures, or characteristics described in connection with the embodiments may be included in at least one embodiment of the present disclosure. Thus, the appearances of “embodiment” in various places throughout the specification do not necessarily refer to the same embodiment, nor is it an independent or alternative embodiment that is mutually exclusive from other embodiments. It is explicitly and implicitly understood by those skilled in the art that the embodiments described in the disclosure may be combined with other embodiments.

It is to be understood that the terms “first” “second”, “third”, “fourth” and so on used in this disclosure may be used herein to describe various elements, but these elements are not limited by these terms. These terms are only used to distinguish the first element from the other element.

It is to be understood that “connection” in the following embodiments should be understood as “electrical connection”, “communication connection”, etc. if the connected circuits, modules, units, etc. have transmissions of the electrical signals or data with each other.

As used herein, the singular forms “a” “an” and “the/this” can include the plural forms as well, unless the context clearly dictates otherwise. It should also be understood that the term “include/contain” or “have” etc., specifies the presence of stated features, integers, steps, operations, components, portions, or combinations thereof, but does not rule out the possibility of the presence or addition of one or more other features, integers, steps, operations, components, portions, or combinations thereof. Furthermore, the term “and/or” as used in this description includes any and all combinations of related listed items.

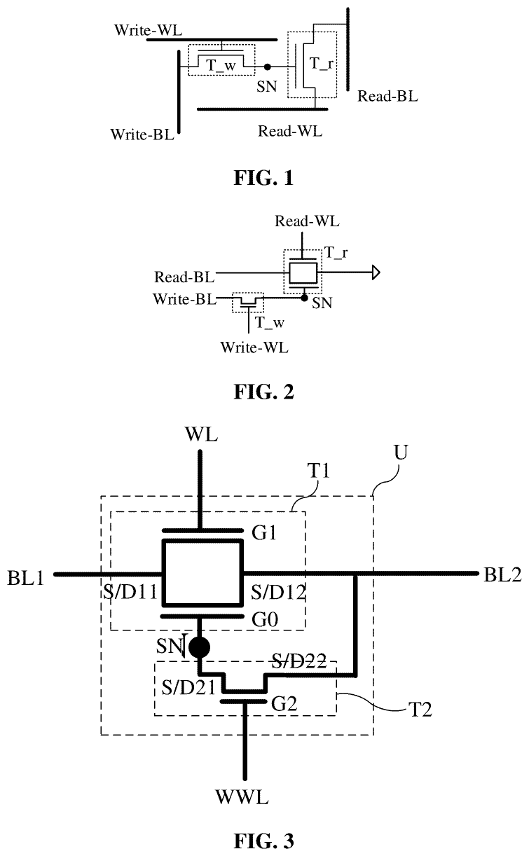

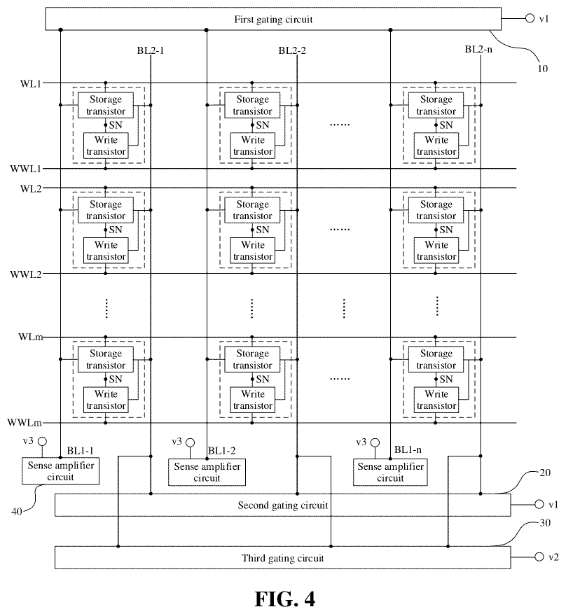

FIG. 1 and FIG. 2 illustrate schematic circuit diagrams of memory cells with two common 2T0C architectures in the related art, respectively.

In some embodiments, as illustrated in FIG. 1, the memory cell includes a read transistor T_r and a write transistor T_w that are connected with each other. A gate of the write transistor T_w is connected to a write word line Write-WL, a first electrode of the write transistor T_w is connected to the write bit line Write-BL, a second electrode of the write transistor T_w is connected to a gate of the read transistor T_r at the storage node SN, the first electrode of the read transistor T_r is connected to the read word line Read-WL, and the second electrode of the read transistor T_r is connected to the read bit line Read-BL.

In other embodiments, as illustrated in FIG. 2, the memory cell includes a read transistor T_r and a write transistor T_w that are connected with each other. The gate of the write transistor T_w is connected to the write word line Write-WL, the first electrode of the write transistor T_w is connected to the write bit line Write-BL, the second electrode of the write transistor T_w is connected to the storage gate of the read transistor T_r at the storage node SN, the control gate of the read transistor T_r is connected to the read word line Read-WL, the first electrode of the read transistor T_r is connected to the read word line Read-WL, and the second electrode of the read transistor T_r is connected to the grounded voltage terminal.

The two kinds of memory cells provided in the aforementioned embodiments both employ the 2T0C architecture, and in the memory cells, the operations of the read transistor T_r when the data reading is implemented is relatively independent from the operations of the write transistor T_w when the data writing is implemented. That is to say, the data writing is performed depending on the turned-on write transistor T_w while keeping the read transistor T_r in the off state; and the data reading is performed depending on whether the read transistor T_r is turned on while keeping the write transistor T_w in the off state. However, due to the limitation of the production process and the operate durations of the transistors, the threshold voltage of each transistor (especially, the read transistor T_r) is easily changed, which inevitably adversely affects data reading and affects the accuracy of data reading.

Some embodiments of the present disclosure provide a new circuit design and driving method of the memory cell. Herein, the memory cell has two transistors (2T) and one capacitor (1C), and both the 2T participate in the pre-charging and the data writing, to implement compensation of the read transistor Vth in the writing stage.

Some embodiments of the present disclosure provide a data read/write circuit and a method for data read/write, a memory and a method for driving a memory, and an electronic device. It is possible to provide different electrical signals to the storage transistor by respectively using a data signal line (i.e., the first bit line) and an auxiliary signal line (i.e., the second bit line) at different stages of a data read/write cycle, and controlling of the control voltages of both the storage transistor and the write transistor is combined, so that the threshold compensation voltage of the storage transistor is retained in the storage node while writing data into the storage node in the data writing stage. In this way, it is convenient to read data that is not affected by the threshold voltage of the storage transistor through the data signal line (i.e., the first bit line) in the data reading stage, thereby ensuring the accuracy of reading the stored data, and further improving the performance of the memory. The data signal line (or the first bit line) may not only supply a data voltage of data to be written into the storage transistor in the data writing stage, but also read the written data in response to whether the storage transistor is turned on in the data reading stage.

In at least some embodiments of the present disclosure, the storage transistor may be understood as the read transistor at least having the function of the data reading. The read transistor or the storage transistor also participates in the pre-charging and the data writing in the data writing stage, and is configured to read data in the reading stage.

It is to be understood that a memory generally includes multiple memory cells, and all memory cell may be arranged in a two-dimensional single layer distribution or in a three-dimensional multi-layer distribution. In order to facilitate description and understanding, the data read/write circuit and the method for data read/write in the following embodiments are introduced by taking one memory cell and driving corresponding to the memory cell as examples. Furthermore, when the solutions provided by the embodiments of the present disclosure are introduced, the data read/write circuit mentioned in the embodiments of the present disclosure mainly refers to a circuit in the memory cell array, and does not include peripheral circuits (such as a row address selection driving circuit, a column address selection driving circuit, etc.). The data read/write circuit includes components of at least one memory cell and a driving line connected with the memory cell.

With reference to FIG. 3, the data read/write circuit provided by some embodiments of the present disclosure includes: a memory cell U, a data signal line BL1, and an auxiliary signal line BL2.

The memory cell U is configured to store data and includes a storage transistor T1 and a write transistor T2 that are connected with each other.

As illustrated in FIG. 3, the storage transistor T1 includes a storage gate G0, a first gate G1, a first electrode S/D11, and a second electrode S/D12. The write transistor T2 includes a second gate G2, a first electrode S/D21, and a second electrode S/D22. The first gate G1 is connected to the first control signal line WL. The second gate G2 is connected to the second control signal line WWL. The first electrode S/D11 of the storage transistor T1 is connected to the data signal line BL1. The first electrode S/D21 of the write transistor T2 is connected to the storage gate G0. The second electrode S/D12 of the storage transistor T1 and the second electrode S/D22 of the write transistor T2 are respectively connected to the auxiliary signal line BL2. The intersection where the first electrode S/D21 of the write transistor T2 is connected to the storage gate G0 is the storage node SN.

The data read/write timing of the memory cell U includes: a data writing stage, a data reading stage, and a standby stage (which may be understood as a stand by stage) preceding the data writing or the data reading. Herein, in the embodiments of the present disclosure, the data read/write timing further includes a pre-charging stage preceding the data writing stage, and a data retention stage following the data writing stage.

The data signal line BL1 is connected to the storage transistor T1 and configured to: supply a first reference voltage to the storage transistor T1 in the standby stage and the pre-charging stage, write data into the storage transistor T1 in the data writing stage, and read data in response to whether the storage transistor T1 is turned on in the data reading stage.

The auxiliary signal line BL2 is connected to the storage transistor T1 and the write transistor T2 and configured to: supply the first reference voltage to both the storage transistor T1 and the write transistor T2 in the standby stage and the pre-charging stage, be floated in the data writing stage, and supply the second reference voltage to both the storage transistor T1 and the write transistor T2 in the data reading stage.

In the embodiments of the present disclosure, a sum of a maximum data voltage corresponding to data capable of being stored by the memory cell U and a threshold voltage of the storage transistor T1 is a reference voltage, and the first reference voltage supplied by the data signal line BL1 and the auxiliary signal line BL2 is greater than the reference voltage.

Herein, the maximum data voltage corresponding to data capable of being stored by the memory cell U refers to a voltage having the largest absolute value of a data voltage corresponding to data among data capable of being stored by the memory cell U, for example, data “1” or data “0”. For example, the data capable of being stored by the memory cell U includes the data “0” and the data “1”. A data voltage Vdatal1 corresponding to the data “1” and a data voltage Vdata0 corresponding to the data “0” may be both positive voltages or negative voltages. Furthermore, the absolute value of the data voltage Vdatal1 corresponding to the data “1” is larger than the absolute value of the data voltage Vdata0 corresponding to the data “0”. Based on this, the data voltage corresponding to the data “1” may be the maximum data voltage of the data capable of being stored by the memory cell U, and vice versa.

It is to be understood that when the data voltage Vdatal1 corresponding to the data “1” is the maximum data voltage of the data capable of being stored by the memory cell U, the sum of the maximum data voltage and the threshold voltage Vth of the storage transistor T1 is the reference voltage, i.e., the reference voltage is Vdata1+Vth. Herein, the reference voltage is a given definition of the sum of the maximum data voltage and the threshold voltage Vth of the storage transistor T1 for convenience of description, and is only used to illustrate a value range of the first reference voltage when the reference voltage is used as a reference standard. For example, the first reference voltage is greater than the reference voltage (i.e. greater than Vdata1+Vth). Furthermore, a difference between the first reference voltage and the reference voltage may be reasonably set according to the requirements.

Exemplarily, the second reference voltage is less than the first reference voltage. Both the storage transistor T1 and the write transistor T2 being N-type transistors is taken as an example, the first reference voltage may be supplied by a first reference voltage terminal. For example, the first reference voltage terminal is a power supply voltage terminal that may supply a rated high-level voltage. The second reference voltage may be supplied by a second reference voltage terminal. For example, the second reference voltage terminal may be a common voltage terminal that may supply a rated low-level voltage.

Exemplarily, the second reference voltage is greater than a minimum data voltage of data capable of being stored by the memory cell U and less than the maximum data voltage of the data capable of being stored by the memory cell U. For example, Vdata1>second reference voltage>Vdata0.

Herein, it is to be understood that in the practical applications of the data read/write circuit, considering the coupling effect between the data signal line BL1 and the auxiliary signal line BL2, the second reference voltage V2 may be greater than the sum of the minimum data voltage and the voltage variation (that is a vector) caused by the coupling effect, and may be less than the sum of the maximum data voltage and the voltage variation (that is a vector) caused by the coupling effect, so as to clearly distinguish the voltage change or the current change caused by the data “1” and caused by the data “0” in the data reading stage. Moreover, since different timings and/or different control voltages bring different coupling effects to the data read/write circuit, the aforementioned voltage variation (vector) may be specifically determined according to the actual situation.

In some embodiments, with continued reference to FIG. 3, the data read/write circuit further includes a first control signal line WL and a second control signal line WWL. The storage transistor T1 includes the storage gate G0, the first gate G1, the first electrode S/D11, and the second electrode S/D12. The write transistor T2 includes the second gate G2, the first electrode S/D21, and the second electrode S/D22. The first gate G0 is connected to the first control signal line WL. The second gate G2 is connected to the second control signal line WWL. The first electrode S/D11 of the storage transistor T1 is connected to the data signal line BL1. The first electrode S/D21 of the write transistor T2 is connected to the storage gate G0. The intersection where the first electrode S/D21 of the write transistor T2 is connected to the storage gate G0 is the storage node SN. The second electrode S/D12 of the storage transistor T1 and the second electrode S/D22 of the write transistor T2 are respectively connected to the auxiliary signal line BL2.

Herein, in order to match the transfer direction, among the first electrode S/D11 and the second electrode S/D12 of the storage transistor T1, one of them may be a source and the other of them may be a drain; and among the first electrode S/D21 and the second electrode S/D22 of the write transistor T2, one of them may be a source and the other of them may be a drain.

Furthermore, it is to be understood that a dual-gate structure is employed for the aforementioned storage transistor T1. The first gate G1 is a control gate of the storage transistor T1, and is configured to control the storage transistor T1 to be turned on and turned off. The storage gate G0 is a floating gate and is configured to capture charges to store data. Accordingly, the storage gate G0 of the storage transistor T1 may also be equivalently drawn as a capacitor in other equivalent circuit diagrams.

Furthermore, in aforementioned some embodiments, the threshold voltage of the storage transistor T1 refers to the threshold voltage Vth corresponding to the storage gate G0 of the storage transistor T1 when the first control signal line WL supplies a preset voltage to the first gate G1.

Exemplarily, the storage transistor T1 is the N-type transistor, and the preset voltage supplied by the first control signal line WL to the first gate G1 is a fixed high-level voltage, however, which is not limited. For example, the P-type transistor is employed for the storage transistor T1, so that the voltage signals of other components connected to the first gate G1 and the storage transistor T1 may be adaptively adjusted, to implement the data reading and writing, which is also allowed. Similarly, it is also allowed that the N-type transistor or the P-type transistor is employed for the write transistor T2.

In view of above, when the data voltage Vdatal1 corresponding to the data “1” is the maximum data voltage of the data capable of being stored by the memory cell U, the reference voltage is Vdata1+Vth, and the first reference voltage is larger than Vdata1+Vth. Furthermore, a difference between the first reference voltage and the reference voltage may be reasonably set according to the requirements.

In the embodiments of the present disclosure, by providing that the data signal line BL1 is connected to the storage transistor T1 of the memory cell U, and the auxiliary signal line BL2 is connected to the storage transistor T1 and the write transistor T2 of the memory cell U, it is possible to provide different electrical signals to the storage transistor T1 by respectively using the data signal line BL1 and the auxiliary signal line BL2 at different stages of the data read/write cycle, and controlling of the control voltages of both the storage transistor T1 and the write transistor T2 is combined, so that the threshold compensation voltage of the storage transistor T1 is retained in the storage node SN while writing data into the storage node SN in the data writing stage. In this way, it is convenient to read data that is not affected by the threshold voltage of the storage transistor through the data signal line BL1 in the data reading stage, thereby ensuring the accuracy of reading the stored data, and further improving the performance of the memory. In addition, in the data read/write circuit provided by the embodiments of the present disclosure, it is not necessary to provide a grounded terminal in the memory cell U, which is also beneficial to further realize the high-density integration of the memory cells U.

It is to be added that in some embodiments, the first control signal line is connected to the first gate G1 of the storage transistor T1 and is configured to: control the storage transistor T1 to be turned off in the standby stage, apply a first write control voltage to the storage transistor T1 in the pre-charging stage and the data writing stage, and apply a read control voltage to the storage transistor T1 in the data reading stage. The second control signal line WWL is connected to the second gate G2 of the write transistor T2 and configured to: control the write transistor T2 to be turned off in the standby stage and the data reading stage, and control the write transistor T2 to be turned on in the data writing stage. The control voltage for the second control signal line WWL to control the write transistor T2 to be turned on is the second write control voltage.

Herein, it is to be understood that the turn-off of the storage transistor T1 may be controlled by a first turn-off control voltage applied by the first control signal line WL to the first gate G1. The turn-off of the write transistor T2 may be controlled by a second turn-off control voltage applied by the second control signal line WWL to the second gate G2.

Exemplarily, the first turn-off control voltage is the same as the second turn-off control voltage.

Exemplarily, both the storage transistor T1 and the write transistor T2 are the N-type transistors. Accordingly, both the first write control voltage and the second write control voltage are the high-level voltages. Both the first turn-off control voltage and the second turn-off control voltage are the low-level voltages. Furthermore, the first write control voltage may be less than the second write control voltage, and the first write control voltage may be reasonably set according to the requirements.

In other embodiments, the write cycle further includes: a data retention stage following the data writing stage.

In some examples, the data signal line BL1 is further configured to: supply the first reference voltage to the storage transistor T1 in the data retention stage. The second control signal line WWL is further configured to: control the write transistor T2 to be turned off after a voltage of the data signal line BL1 is the first reference voltage in the data retention stage. The auxiliary signal line BL2 is further configured to: supply the first reference voltage to both the storage transistor T1 and the write transistor T2 after the write transistor T2 is turned off in the data retention stage.

In addition, the first control signal line WL is further configured to: apply the first turn-off control voltage to the storage transistor T1 after the write transistor T2 is turned off in the data retention stage.

In the embodiments of the present disclosure, in the data retention stage after the data data is written into the storage node SN, the voltage of the data signal line BL1 may be pulled up to the first reference voltage V1, and the storage transistor T1 may be turned off through the voltage difference between the first electrode S/D11 of the storage transistor T1 and the storage node SN. In this case, the write transistor T2 connecting the storage node SN and the auxiliary signal line BL2 is in the on state, and the voltage of the storage node SN may be kept to be stable based on the coupling effect between the data signal line BLI and the auxiliary signal line BL2. Then, the write transistor T2 is turned off firstly, and the first reference voltage is supplied to both the storage transistor T1 and the write transistor T2 through the auxiliary signal line BL2, which can prevent the leakage current generated in the write transistor T2, thereby retaining the data data in the storage node SN.

It is to be understood that in the data reading stage, the data signal line BL1 reads the data data in response to whether the storage transistor T1 is turned on, which may be manifested as: reading the data data through a change in the current or voltage transferred by the data signal line BL1. Therefore, in the data retention stage, the first turn-off control voltage may also be applied to the storage transistor T1 by using the first control signal line WL after the write transistor T2 is turned off. In this way, not only can the off state of the storage transistor T1 be further ensured to avoid the leakage current generated in the storage transistor T1, but also it is convenient to subsequently apply the read control voltage to the storage transistor T1 through the first control signal line WL, to implement the read scan control of the data data.

In other examples, the first control signal line WL is further configured to: control the storage transistor T1 to be turned off earlier than the write transistor T2 in a data retention stage. The data signal line BL1 is further configured to: supply the first reference voltage to the storage transistor T1 after the storage transistor T1 is turned off in the data retention stage. The second control signal line WWL is further configured to: control the write transistor T2 to be turned off after the data signal line BL1 supplies the first reference voltage in the data retention stage. The auxiliary signal line BL2 is further configured to: supply the first reference voltage to both the storage transistor T1 and the write transistor T2 after the write transistor T2 is turned off in the data retention stage.

In the embodiments of the present disclosure, after the data data is written into the storage node SN, the storage transistor T1 may be turned off firstly and then the voltage of the data signal line BL1 may be pulled up to the first reference voltage V1. In this case, the write transistor T2 connecting the storage node SN and the auxiliary signal line BL2 is kept to be in the on state, and the voltage of the storage node SN may be kept to be stable. Then, the write transistor T2 is turned off, and the first reference voltage is supplied to both the storage transistor T1 and the write transistor T2 through the auxiliary signal line BL2, which can prevent the leakage current generated in the write transistor T2, thereby stabilizing the data data in the storage node SN.

It is to be noted that the aforementioned controlling of the storage transistor T1 by the first control signal line WL and the controlling of the write transistor T2 by the second control signal line WWL may be referred to the method for the data read/write described later for details. Herein, only the connection relationships and basic functions of the first control signal line WL and the second control signal line WWL are described.

In some embodiments, the write control voltages supplied by the first control signal line WL and the second control signal line WWL is pulse voltages.

In some embodiments, the first write control voltage supplied by the first control signal line WL in the write cycle may be the same or different from the read control voltage supplied by the first control signal line WL in the read cycle.

Exemplarily, the first write control voltage is the same as the read control voltage. Both the storage transistor T1 and the write transistor T2 being the N-type transistors is taken as an example, both the first write control voltage and the read control voltage are the high-level voltages. Both the storage transistor T1 and the write transistor T2 being the P-type transistors is taken as an example, both the first write control voltage and the read control voltage are the low-level voltages.

Exemplarily, the first write control voltage is less than the read control voltage. For example, the voltage absolute value of the first write control voltage is less than the voltage absolute value of the read control voltage.

The foregoing is the memory cell and the method for driving a memory cell provided by the embodiments of the present disclosure, a memory array including the memory cell will be described below.

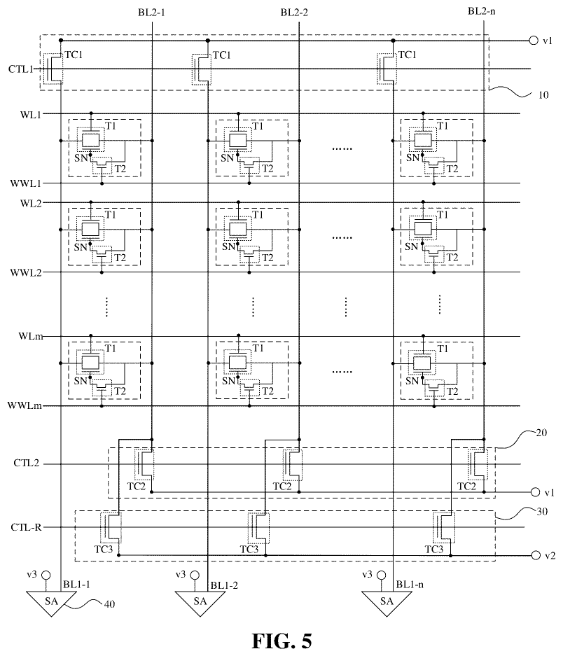

In some embodiments, with reference to FIG. 4 and FIG. 5, the number of the memory cells U is multiple. The multiple memory cells U are arranged in a row in a first direction and arranged in a column in a second direction; and the first direction intersects with the second direction. Herein, for example, the first direction is an extending direction of the first control signal line WL and/or the second control signal line WWL; for example, the second direction is an extending direction of the data signal line BL1 and/or the auxiliary signal line BL2; and for example, the first direction is orthogonal to the second direction.

Exemplarily, the multiple memory cells U may be distributed in an array of m×n.

Exemplarily, as illustrated in FIG. 4 and FIG. 5, one column of memory cells U shares one data signal line BL1 and one auxiliary signal line BL2. A row of the memory cells U share one first control signal line WL and one second control signal line WWL.

Exemplarily, the coupling capacitance between the data signal line BL1 and the storage gate G0 (which may be equivalent to the storage node SN) is less than the first target threshold. The coupling capacitance between the auxiliary signal line BL2 and the storage gate G0 (which may be equivalent to the storage node SN) is less than the second target threshold. Herein, the first target threshold value may be the same as or different from the second target threshold value.

Furthermore, both the first target threshold value and the second target threshold value may adopt the smaller values.

Exemplarily, the coupling capacitance between the data signal line BL1 and the storage gate G0 (which may be equivalent to the storage node SN) is the first coupling capacitance. The coupling capacitance between the data signal line BL1 and the auxiliary signal line BL2 is a second coupling capacitance. The ratio of the first coupling capacitance and the second coupling capacitance is less than the target value. Furthermore, the target value is as small as possible.

In some embodiments, with continued reference to FIG. 4 and FIG. 5, the data read/write circuit further includes: a first reference voltage terminal v1 and a second reference voltage terminal v2.

The first reference voltage terminal v1 is correspondingly connected to the data signal line BL1 through a first gating circuit 10 and correspondingly connected to the auxiliary signal line BL2 through a second gating circuit 20. The first reference voltage terminal v1 is configured to supply the first reference voltage. The first gating circuit 10 is configured to: selectively connect the first reference voltage terminal v1 to the data signal line BL1 in the standby stage and the pre-charging stage. The second gating circuit 20 is configured to: selectively connect the first reference voltage terminal v1 to the auxiliary signal line BL2 in the standby stage and the pre-charging stage.

The second reference voltage terminal v2 is correspondingly connected to the auxiliary signal line BL2 through a third gating circuit 30. The second reference voltage terminal v2 is configured to supply the second reference voltage. The third gating circuit 30 is configured to: selectively connect the second reference voltage terminal v2 to the auxiliary signal line BL2 in the data reading stage.

Exemplarily, the first reference voltage terminal v1 connected to the data signal line BL1 and the first reference voltage terminal v1 connected to the auxiliary signal line BL2 may be the same voltage terminal, or may be different voltage terminals providing the same voltage.

Furthermore, the first reference voltage terminal v1 connected to the data signal line BL1 and the first reference voltage terminal v1 connected to the auxiliary signal line BL2 are different voltage terminals providing the same voltage, and the different voltage terminals may be provided in different regions. For example, different voltage terminals are provided on opposite sides of the memory cell U array, respectively.

In some embodiments, as illustrated in FIG. 5, the first gating circuit 10 includes first selection transistors TC1 connected to various data signal lines BL1 in one-to-one correspondence. A gate of each first selection transistor TC1 is connected to the first gating signal line CTL1. A first electrode of each first selection transistor TC1 is connected to a corresponding data signal line BL1. A second electrode of each first selection transistors TC1 is connected to the first reference voltage terminal v1.

The second gating circuit 20 includes second selection transistors TC2 connected to various auxiliary signal lines BL2 in one-to-one correspondence. A gate of each second selection transistor TC2 is connected to the second gating signal line CTL2. A first electrode of each second selection transistor TC2 is connected to a corresponding auxiliary signal line BL2. A second electrode of each second selection transistor TC2 is connected to the first reference voltage terminal v1.

The third gating circuit 30 includes third selection transistors TC3 connected to various auxiliary signal lines BL2 in one-to-one correspondence. A gate of each third selection transistor TC3 is connected to the read gating line CTL-R. A first electrode of each third selection transistor TC3 is connected to a corresponding auxiliary signal line BL2. A second electrode of each third selection transistor TC3 is connected to the second reference voltage terminal v2.

Among the first electrode and the second electrode of each selection transistor mentioned in aforementioned some embodiments, one of them may be a source and the other may be a drain. Furthermore, one of the selection transistors may be selected to be turned on in response to a gating signal supplied by corresponding gating signal line, to achieve read/write controlling of each memory cell U.

In some embodiments, with continued reference to FIG. 4 and FIG. 5, the data read/write circuit further includes one or more sense amplifier circuits 40. For example, the data read/write circuit includes multiple sense amplifier circuits 40 in one-to-one correspondence with the data signal lines BL1. Furthermore, one terminal of each data signal line BL1 that is remote from the first reference voltage terminal v1 is connected to the corresponding sense amplifier circuit 40, to read data.

Herein, in order to match the manner where the data read/write circuit reads data, a current sense amplifier circuit or a voltage sense amplifier circuit may be employed for the sense amplifier circuit 40.

Exemplarily, the sense amplifier circuit 40 is the current sense amplifier circuit. In this way, in the data reading stage, the data signal line BLI continuously supplies the first reference voltage, and in response to whether the storage transistor T1 is turned on, the sense amplifier circuit 40 may read data by sensing a change in the current transferred by the data signal line BL1.

Exemplarily, the sense amplifier circuit 40 is the voltage sense amplifier circuit. In the data reading stage, in response to whether the storage transistor T1 is turned on, the first reference voltage pre-supplied by the data signal line BL1 may change or may not change, so that the sense amplifier circuit 40 may read data by sensing a change in the voltage transferred by the data signal line BL1.

Furthermore, the circuit structure of the sense amplifier circuit 40 is not limited in the embodiments of the present disclosure. In some examples, the sense amplifier circuit 40 is the voltage sense amplifier circuit, such as, a comparison amplifier circuit. The sense amplifier circuit 40 may be connected to the third reference voltage terminal v3, to read data by comparing the difference between the third reference voltage supplied by the third reference voltage terminal v3 and the voltage transferred by the data signal line BL.

It is to be added that, in the aforementioned some embodiments, the understanding is made with reference to FIG. 4 and FIG. 5, both the first write control voltage supplied by the first control signal line WL and the second write control voltage supplied by the second control signal line WWL are control voltages supplied when the data writing is performed on the memory cell U. Based on this, it can be understood that for the memory cell U array, in addition to supplying the aforementioned first write control voltage and the second write control voltage to the row of the memory cells U on which the data writing is performed, the first control signal lines WL and the second control signal lines WWL corresponding to other rows of the memory cells U may be supplied with the turn-off control voltage, so that the row scan writing of the memory cell U array can be implemented.

Some embodiments of the present disclosure also provide a method for data read/write, to implement the data read/write process of the data read/write circuit. The method for data read/write may be applied to any one of the memory cells, and the memory cell is configured to store data, and the structure of the memory cell may be referred to the related description in the aforementioned some embodiments. The method for data read/write also has the technical advantages that exist for the aforementioned data read/write circuit.

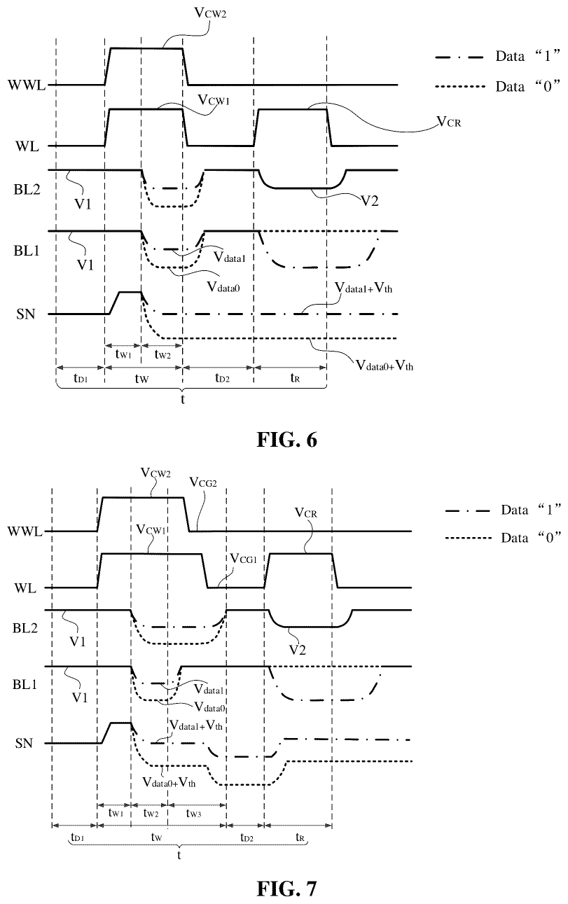

The understanding is made with reference to FIG. 3, FIG. 6, FIG. 7, and FIG. 8, in the method for data read/write provided by some embodiments of the present disclosure, the data read/write cycle t of the memory cell U includes a write cycle tW, a read cycle tR, and a standby stage (for example, a first standby stage tD1 and a second standby stage tD2).

In some embodiments, as illustrated in FIG. 6, the write cycle tW includes a pre-charging stage tW1 and a data writing stage tW2. The method for data read/write includes operation S100 and operation S200.

In operation S100, in the pre-charging stage tW1, a data signal line BL1 supplies a first reference voltage V1 to the storage transistor T1; an auxiliary signal line BL2 supplies the first reference voltage V1 to both the storage transistor T1 and the write transistor T2; and the write transistor T2 is turned on to pre-charge a storage node SN. Herein, a sum of a maximum data voltage corresponding to the data capable of being stored by the memory cell U and a threshold voltage Vth of the storage transistor T1 is a reference voltage; and the first reference voltage V1 is greater than the reference voltage.

Herein, after the pre-charging of the storage node SN is completed, the voltage of the storage node SN is the first reference voltage V1.

Exemplarily, the data capable of being stored by the memory cell U includes data “0” and data “1”. A data voltage Vdatal1 corresponding to the data “1” is greater than a data voltage Vdata0 corresponding to the data “0”. Based on this, the data voltage Vdatal1 corresponding to the data “1” may be the maximum data voltage of the data capable of being stored by the memory cell U, and vice versa.

Based on this, when the data voltage Vdatal1 corresponding to the data “1” is the maximum data voltage of the data capable of being stored by the memory cell U, the reference voltage is Vdata1+Vth, and the first reference voltage is larger than Vdata1+Vth. Furthermore, a difference between the first reference voltage and the reference voltage may be reasonably set according to the requirements.

Herein, the reference voltage is a given definition of the sum of the maximum data voltage and the threshold voltage Vth of the storage transistor T1 for convenience of description, and is only used to illustrate the value range of the first reference voltage when the reference voltage is used as a reference standard.

In some embodiments, a dual-gate structure including a first gate G1 and a storage gate G0 is employed for the storage transistor T1. The first gate G1 is connected to the first control signal line WL, is a control gate of the storage transistor T1, and is configured to control the storage transistor T1 to be turned on and turned off. The storage gate G0 is connected to the write transistor T2, is a floating gate, and is configured to capture charges to store data. Furthermore, the threshold voltage Vth of the storage transistor T1 refers to the threshold voltage Vth corresponding to the storage gate G0 of the storage transistor T1 when the first control signal line WL supplies a preset voltage to the first gate G1.

Exemplarily, the storage transistor T1 is the N-type transistor, and the preset voltage supplied by the first control signal line WL to the first gate G1 is a fixed high-level voltage, however, which is not limited. For example, the P-type transistor is employed for the storage transistor T1, so that the voltage signals of other components connected to the first gate G1 and the storage transistor T1 may be adaptively adjusted, to implement the data reading and writing, which is also allowed. Similarly, it is also allowed that the N-type transistor or the P-type transistor is employed for the write transistor T2.

Furthermore, the second gate G2 of the write transistor T2 is connected to the second control signal line WWL, and the write transistor T2 may be turned on or turned off in response to a control signal supplied by the second control signal line WWL. For convenience of description, in some embodiments below, both the storage transistor T1 and the write transistor T2 being the N-type transistors is taken as an example to describe.

In some embodiments, with continued reference to FIG. 3, FIG. 6, FIG. 7, and FIG. 8, in the pre-charging stage tW1, the first control signal line WL supplies a first write control voltage VCW1 to the first gate G1 of the storage transistor T1. The second control signal line WWL supplies the second write control voltage VCW2 to the second gate G2 of the write transistor T2. In this case, the data signal line BL1 supplies a first reference voltage V1 to the first electrode of the storage transistor T1; the auxiliary signal line BL2 supplies the first reference voltage V1 to the second electrode of the storage transistor T1; and the storage transistor T1 is in the off state. Exemplarily, both the first write control voltage VCW1 and the second write control voltage VCW2 are the high-level voltages.

Exemplarily, the first write control voltage VCW1 is less than the second write control voltage VCW2, and the first write control voltage VCW1 may be reasonably set according to the requirements.

In operation S200, the data writing stage tW2, in response to a write command, the auxiliary signal line BL2 is floated, and the data signal line BL1 supplies a data voltage Vdata to the storage transistor T1. The storage transistor T1 is turned on; and the storage node SN is discharged to be in the stable state to write the data data corresponding to the data voltage Vdata.

Herein, the storage node SN is discharged to be in the stable state, which means that the voltage change of the storage node SN tends to zero. After the storage node SN is discharged to be in the stable state, the voltage of the storage node SN is Vdata+Vth (including approximately equal to Vdata+Vth).

Furthermore, as illustrated in FIG. 6, FIG. 7, and FIG. 8, in the data writing stage tW2, the first control signal line WL continuously supplies the first write control voltage VCW1 to the first gate G1 of the storage transistor T1. The second control signal line WWL continuously supplies the second write control voltage VCW2 to the second gate G2 of the write transistor T2. In this case, the data signal line BL1 supplies the data voltage Vdata to the first electrode of the storage transistor T1; the auxiliary signal line BL2 is floated; and the storage transistor T1 is in the on state.

Furthermore, the data voltage Vdata supplied by the data signal line BL1 is associated with the data to be written. For example, the data to be written is the data “1”, and the data voltage supplied by the data signal line BL1 in the data writing stage tW2 is Vdata1. Alternatively, for another example, the data to be written is the data “0”, and the data voltage supplied by the data signal line BL1 in the data writing stage tW2 is Vdata0.

In some embodiments, the understanding is made with reference to FIG. 4 and FIG. 5, the auxiliary signal line BL2 is connected to the first reference voltage terminal v1 through the second gating circuit 20, and is connected to the second reference voltage terminal v2 through the third gating circuit 30. The auxiliary signal line BL2 is floated, which means that both the second gate circuit 20 and the third gate circuit 30 that are connected to the auxiliary signal line BL2 are in the off state, and there is no signal inputted into the terminal of the auxiliary signal line BL2 that is connected the second gating circuit 20 and the third gating circuit 30.

In some embodiments, the write cycle tW further includes: a data retention stage tW3 following the data writing stage tW2.

In some examples, with reference to FIG. 7, the method for data read/write further includes operation S300.

In operation S300, in the data retention stage tW3, a voltage of the data signal line BL1 is pulled up to the first reference voltage V1, the write transistor T2 is turned off after the voltage of the data signal line BL1 is the first reference voltage V1, and then a voltage of the auxiliary signal line BL2 is pulled up to the first reference voltage V1.

In addition, with continued reference to FIG. 7, after the write transistor T2 is turned off, the method for data read/write further includes: a first turn-off control voltage VCG1 is applied to the storage transistor T1.

In the embodiments of the present disclosure, in the data retention stage tW3 after the data data is written into the storage node SN, the voltage of the data signal line BL1 may be pulled up to the first reference voltage V1, and the storage transistor T1 may be turned off by the voltage difference between the first electrode S/D11 of the storage transistor T1 and the storage node SN. In this case, the write transistor T2 connecting the storage node SN and the auxiliary signal line BL2 is in the on state, and the voltage of the storage node SN may be kept to be stable (for example, the voltage of the storage node SN may be kept to be Vdata+Vth) based on the coupling effect between the data signal line BL1 and the auxiliary signal line BL2. Then, the write transistor T2 is turned off firstly, and the first reference voltage V1 is supplied to both the storage transistor T1 and the write transistor T2 through the auxiliary signal line BL2, so that the data data may be retained in the storage node SN (the voltage of the storage node SN is Vdata+Vth).

It is to be understood that in the data reading stage tR, the data signal line BL1 reads the data data in response to whether the storage transistor T1 is turned on, which may be manifested as reading the data data through a change in the current or voltage transferred by the data signal line BL1. Therefore, in the data retention stage tW3, the first turn-off control voltage VCG1 may also be applied to the storage transistor T1 by using the first control signal line WL after the write transistor T2 is turned off. In this way, not only can the off state of the storage transistor T1 be further ensured to avoid the generation of the leakage current, but also it is convenient to subsequently apply the read control voltage VCR to the storage transistor T1 through the first control signal line WL, to implement the read scan control of the data data.

Herein, with reference to FIG. 7, in the data retention stage tW3, after the write transistor T2 is turned off, the voltage of the auxiliary signal line BL2 is firstly pulled up to the first reference voltage V1, or the first turn-off control voltage VCG1 is firstly applied to the storage transistor T1 through the first control signal line WL. Alternatively, both the operations of the pulling up and the applying are performed, which also is allowed.

Furthermore, after the write transistor T2 is turned off, when the first control signal line WL applies the first turn-off control voltage VCG1 to the storage transistor T1, the voltage of the storage node SN changes accordingly. For example, the first turn-off control voltage VCG1 is a low-level voltage, if the data written into the storage node SN is the data “1”, the voltage of the storage node SN may be changed as: Vdata1+Vth−ΔV; and if the data written into the storage node SN is the data “0”, the voltage of the storage node SN may be changed as: Vdata0+Vth−ΔV.

Accordingly, in the subsequent data reading stage tR, when the first control signal line WL applies the read control voltage VCR to the storage transistor T1, the voltage of the storage node SN changes accordingly. For example, the read control voltage VCR is a high-level voltage, if the data written into the storage node SN is the data “1”, the voltage of the storage node SN may be changed as: Vdata1+Vth−ΔV+ΔV′; and if the data written into the storage node SN is the data “0”, the voltage of the storage node SN may be changed as: Vdata0+Vth−ΔV+ΔV′.

In the embodiment of the present disclosure, although the voltage of the storage node SN changes after the first control signal line WL applies the first turn-off control voltage VCG1 or the read control voltage VCR to the storage transistor T1, the voltage of the storage node SN always includes the data voltage Vdata corresponding to the written data and the threshold voltage Vth of the storage transistor T1; and the voltage change of the storage node SN is the same for different data voltages (for example, the Vdatal1 and the Vdata0), which does not affect the accuracy of reading the data in the data reading stage tR.

In some examples, with reference to FIG. 8, the method for data read/write further includes operation S300′.

In operation S300′, in the data retention stage tW3, a voltage of the data signal line BL1 is pulled up to the first reference voltage V1, and the storage transistor T1 is turned off; and then the write transistor T2 is turned off and a voltage of the auxiliary signal line BL2 is pulled up to the first reference voltage V1.

Herein, it is to be understood that the turn-off of the storage transistor T1 may be controlled by a first turn-off control voltage VCG1 applied by the first control signal line WL to the first gate G1. The turn-off of the write transistor T2 may be controlled by a second turn-off control voltage VCG2 applied by the second control signal line WWL to the second gate G2.

Exemplarily, the first turn-off control voltage VCG1 is the same as the second turn-off control voltage VCG2.

Exemplarily, both the storage transistor T1 and the write transistor T2 are the N-type transistors. Accordingly, both the first turn-off control voltage VCG1 and the second turn-off control voltage VCG2 are the low-level voltages.

In the embodiments of the present disclosure, after the data data is written into the storage node SN, the storage transistor T1 may be turned off firstly and then the voltage of the data signal line BL1 may be pulled up to the first reference voltage V1. In this case, the write transistor T2 connecting the storage node SN and the auxiliary signal line BL2 is kept to be in the on state, and the voltage of the storage node SN may be kept to be stable (for example, the voltage of the storage node SN may be kept to be Vdata+Vth). Then, the write transistor T2 is turned off, and the first reference voltage is supplied to both the storage transistor T1 and the write transistor T2 through the auxiliary signal line BL2, which can prevent the leakage current generated in the write transistor T2, thereby stabilizing the data data in the storage node SN (for example, the voltage of the storage node SN is Vdata+Vth).

In some embodiments, as illustrated in FIG. 6, FIG. 7, and FIG. 8, the read cycle tR includes a data reading stage tR. The method for data read/write further includes operation S400.

In operation S400, in the data reading stage tR, in response to a read command, a read control voltage VCR is applied to the storage transistor T1 and a second reference voltage V2 is supplied, through the auxiliary signal line BL2, to both the storage transistor T1 and the write transistor T2; where the data signal line BL1 is further configured to: read data in response to whether the storage transistor is turned on.

Exemplarily, the second reference voltage V2 is less than the first reference voltage V1.

Exemplarily, the second reference voltage V2 is greater than a minimum data voltage of data capable of being stored by the memory cell U and less than the maximum data voltage of the data capable of being stored by the memory cell U. For example, Vdata1>V2>Vdata0.

Herein, it is to be understood that in the practical applications of the data read/write circuit, considering the coupling effect between the data signal line BL1 and the auxiliary signal line BL2, the second reference voltage V2 may be greater than the sum of the minimum data voltage and the voltage variation (vector) caused by the coupling effect, and may be less than the sum of the maximum data voltage and the voltage variation (vector) caused by the coupling effect.

Exemplarily, in the data reading stage tR, the first control signal line WL applies the read control voltage VCR to the first gate G1 of the storage transistor T1. The read control voltage VCR may be the same as or different from the first write control voltage VCW1 supplied by the first control signal line WL in the write cycle tW.

Exemplarily, the read control voltage VCR is the same as the first write control voltage VCW1.

Exemplarily, the read control voltage VCR is higher than the first write control voltage VCW1.

Herein, the read control voltage VCR is applied to the storage transistor T1 in response to the read command, which means that it is possible to ensure that the storage transistor T1 is in different states when different pieces of data are stored in the storage node SN by the appropriate voltages applied by the first control signal line WL.

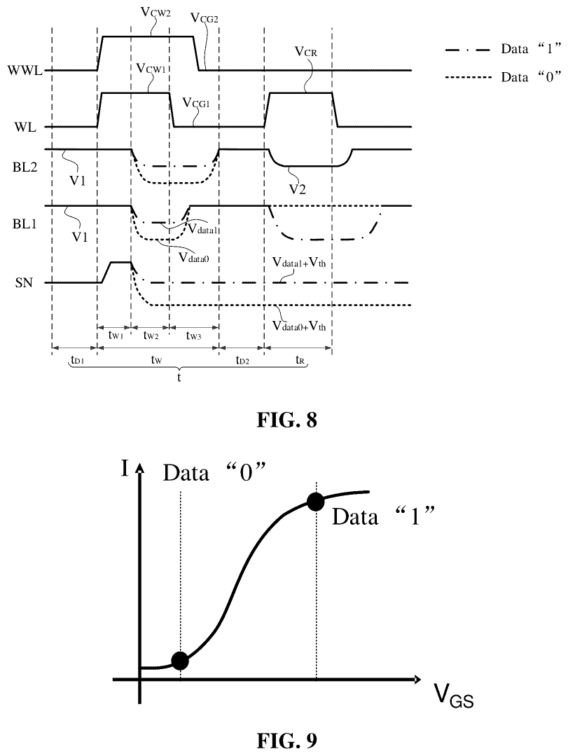

Exemplarily, the understanding is made with reference to FIG. 6, FIG. 7, FIG. 8, and FIG. 9, the data written into the storage node SN includes “1” or “0”. In the data reading stage tR, after the read control voltage VCR is applied to the storage transistor T1, following two cases may exist.

When the data stored in the storage node SN is “1”, the gate-source voltage VGS (i.e., the voltage difference between the storage gate G0 and the second electrode S/D12) of the storage transistor T1 is large and is greater than the threshold voltage Vth of the storage transistor T1, and the storage transistor T1 is in the on state.

When the data stored in the storage node SN is “0”, the gate-source voltage VGS (i.e., the voltage difference between the storage gate G0 and the second electrode S/D12) of the storage transistor T1 is small and is less than the threshold voltage Vth of the storage transistor T1, and the storage transistor T1 is in the off state.

In order to more clearly describe the data reading process of the data reading stage tR, the data reading methods illustrated in FIG. 6 and FIG. 8 are taken as examples, and the data reading method illustrated in FIG. 7 may be adaptively understood.

In the data reading stage tR, if the voltage of the storage gate G0 of the storage transistor T1 is the voltage after the data “1” is written into the storage node SN, i.e., Vdata1+Vth. The voltage of the second electrode S/D12 of the storage transistor T1 is the second reference voltage V2 supplied by the auxiliary signal line BL2. The gate-source voltage VGS of the storage transistor T1 is Vdata1+Vth−V2. Since V2 is less than Vdata1, the gate-source voltage VGS of the storage transistor T1 is greater than the Vth.

In the data reading stage tR, if the voltage of the storage gate G0 of the storage transistor T1 is the voltage after the data “0” is written into the storage node SN, i.e., Vdata0+Vth. The voltage of the second electrode S/D12 of the storage transistor T1 is the second reference voltage V2 supplied by the auxiliary signal line BL2. The gate-source voltage VGS of the storage transistor T1 is Vdata0+Vth−V2. Since V2 is greater than Vdata0, the gate-source voltage VGS of the storage transistor T1 is less than the Vth.

In addition, the understanding is made with reference to FIG. 4, FIG. 5, FIG. 6, FIG. 7, and FIG. 8, in order to match the manner where the data read/write circuit reads data, the manner where the data signal line BL1 reads data in response to whether the storage transistor is turned on may be manifested as: current sense reading or a voltage sense reading.

Exemplarily, in the data reading stage tR, the data signal line BL1 continuously supplies the first reference voltage V1, and in response to whether the storage transistor T1 is turned on, the sense amplifier circuit 40 connected to the data signal line BL1 may read data by sensing a change in the current transferred by the data signal line BL1.

Exemplarily, in the data reading stage tR, in response to whether the storage transistor T1 is turned on, the first reference voltage V1 pre-supplied by the data signal line BL1 may change or may not change, so that the sense amplifier circuit 40 may read data by sensing a change in the voltage transferred by the data signal line BL1.

It is worth mentioning that, in some embodiments, with reference to FIG. 6, FIG. 7, and FIG. 8, the data read/write cycle t further includes a standby stage (i.e., a stand by stage) preceding the pre-charging stage tW1 and/or preceding the data reading stage tR.

Exemplarily, as illustrated in FIG. 7, the data read/write cycle t further includes: a data retention stage tW3 following the data writing stage tW2. The data reading stage tR is following the data retention stage tW3. The standby stage includes a first standby stage tD2 preceding the pre-charging stage tW1, and a second standby stage tD2 following the data retention stage tW3 and preceding the data reading stage tR.

Accordingly, the method for data read/write further includes the following operation.

In the standby stage (including the first standby stage tD2 and the second standby stage tD2), the storage transistor T1 and the write transistor T2 are in the off state, the data signal line BL1 supplies the first reference voltage V1 to the storage transistor T1, and the auxiliary signal line BL2 supplies the first reference voltage V1 to both the storage transistor T1 and the write transistor T2.

In the embodiment of the present disclosure, in the standby stage, the first reference voltage V1 may be supplied to the first electrode of the storage transistor T1 by using the data signal line BL1, and the first reference voltage V1 may be supplied to the second electrode of the storage transistor T2 by using the auxiliary signal line BL2, thereby ensuring that there is no large voltage difference between the first electrode and the second electrode of the storage transistor T1, and effectively reducing the risk of the generation of the leakage current, in particular, when the first reference voltage V1 is the high-level voltage.

In addition, it is to be understood that the first standby stage tD1 and the second standby stage tD2 mentioned in the aforementioned some embodiments are the standby stage mentioned in the aforementioned data read/write circuit. In combination with the foregoing, the first standby stage tD1 is independent of the write cycle tw, and the second standby stage tD2 is independent of the read cycle tR. In some examples, the voltage signals supplied by the data signal line BL1, the auxiliary signal line BL2, the first control signal line WL, and the second control signal line WWL are the same based on the first standby stage tD1 and the second standby stage tD2, and the first standby stage tD1 and the second standby stage tD2 may be regarded as the same standby stage, so that different read/write cycles are entered in response to received different commands. For example, the write cycle is entered when the write command is received, or the read cycle is entered when the read command is received.

It is to be understood that in the first standby stage tD1 and the second standby stage tD2, the first control signal line WL applies the first turn-off control voltage VCG1 to the first gate G1 of the storage transistor T1, and the second control signal line WWL applies the second turn-off control voltage VCG2 to the second gate G2 of the write transistor T2.

Exemplarily, the first turn-off control voltage VCG1 is the same as the second turn-off control voltage VCG2.

Exemplarily, both the storage transistor T1 and the write transistor T2 are the N-type transistors. Both the first turn-off control voltage VCG1 and the second turn-off control voltage VCG2 are the low-level voltages.

In the embodiments of the present disclosure, the memory cell U is configured to store data and includes the storage transistor T1 and the write transistor T2 that are connected with each other. In the embodiments of the present disclosure, by providing that the data signal line BL2 is connected to the storage transistor T1 of the memory cell U, and the auxiliary signal line BL2 is connected to the storage transistor T1 and the write transistor T2 of the memory cell U, in the pre-charging stage tW1, it is possible to pre-charge the storage node SN of the memory cell U after the data signal line BL1 supplies the first reference voltage V1 to the storage transistor T1, the auxiliary signal line BL2 supplies the first reference voltage V1 to both the storage transistor T1 and the write transistor T2, and the write transistor T2 is turned on. Based on the fact that the first reference voltage V1 is greater than the reference voltage (i.e. the sum of the maximum data voltage corresponding to the data capable of being stored in the memory cell U and the threshold voltage of the storage transistor T1, e.g. Vdata1+Vth), i.e. V1>(Vdata1+Vth). In this way, after the storage node SN of the memory cell U is pre-charged, the voltage (= or ≈V1) of the storage node SN may be greater than the reference voltage, e.g. greater than (Vdata1+Vth). In this way, in the data writing stage tW2, after the auxiliary signal line BL2 is floated and the data signal line BL1 supplies the data voltage Vdata to the storage transistor T1 in response to the write command, the storage transistor T1 is turned on, and the storage node SN may be naturally discharged to be in the stable state to write the data data corresponding to the aforementioned data voltage Vdata.

In the embodiments of the present disclosure, since the voltage of the storage node SN after the pre-charging is greater than the reference voltage, for example, greater than (Vdata1+Vth), i.e., the voltage of the storage node SN is not only greater than the data voltage Vdata supplied by the data signal line BL1, but also the difference between the voltage of the storage node SN and the data voltage Vdata is greater than the threshold voltage Vth of the storage transistor T1, after the storage node SN is discharged to be in the stable state, the voltage of the storage node SN corresponds to the sum of the data voltage Vdata and the threshold voltage Vth of the storage transistor T1 (i.e., the voltage of the storage node SN= or ≈Vth), thereby retaining the threshold compensation voltage (= or ≈Vth) of the storage transistor T1 in the storage node SN while writing the data data.

Based on this, after the data data is written, in some embodiments of the present disclosure, the storage transistor T1 and the write transistor T2 may be turned off (see the related description of the data retention stage tW3 for details). Furthermore, in the second standby stage tD2, the first reference voltage V1 may be supplied to the storage transistor T1 by using the data signal line BL1 and the auxiliary signal line BL2, respectively, and the first reference voltage V1 may be supplied to the write transistor T2 by using the auxiliary signal line BL2. In this case, both the storage transistor T1 and the write transistor T2 are in the off state, and the voltage of the storage node SN may be kept stable.

Then, in the data reading stage tR, in response to the read command, the read control voltage VCR may be applied to the storage transistor T1 and a second reference voltage V2 is supplied, through the auxiliary signal line BL2, to both the storage transistor T1 and the write transistor T2. After the data signal line BL1 supplies the first reference voltage V1, the auxiliary signal line BL1 supplies the second reference voltage V2, and the read control voltage VCR is applied to the storage transistor T1, the magnitude of the voltage stored in the storage node SN may affect whether the first electrode and the second electrode of the storage transistor T1 are turned on, so that the data signal line BL1 reads data in response to whether the storage transistor T1 is turned on. Since the voltage stored in the storage node SN includes the threshold compensation voltage (= or ≈Vth) of the storage transistor T1, data read by the data signal line BL1 in response to whether the storage transistor T1 is turned on may not be affected by the threshold voltage Vth of the storage transistor T1, thereby ensuring the accuracy of reading the stored data data, and further improving the memory performance.

Yet another aspect of some embodiments of the present disclosure also provides a memory. The understanding is made with reference to FIG. 3, FIG. 4, and FIG. 5, the memory includes at least one memory cell U, and a first bit line BL1, a second bit line BL2, a first word line WL, and a second word line WWL connected correspondingly to the memory cell U. The memory cell U includes a storage transistor T1 and a write transistor T2. The storage transistor T1 includes a storage gate G0, a first gate G1, a first electrode S/D11, and a second electrode S/D12. The write transistor T2 includes a second gate G2, a first electrode S/D21, and a second electrode S/D22. The storage gate G0 is connected to the first electrode S/D21 of the write transistor T2, and the intersection point where the storage gate G0 is connected to the first electrode S/D21 of the write transistor T2 is the storage node SN. The first word line WL is connected to the first gate G1, and the second word line WWL is connected to the second gate G2. The first bit line BL1 is connected to the first electrode S/D 11 of the storage transistor T1, and the second bit line BL2 is connected to both the second electrode S/D12 of the storage transistor T1 and the second electrode S/D22 of the write transistor T2. The first bit line BL1 is configured to: supply a data voltage of data to be written into the storage transistor in a data writing stage, and read data written into the memory node in response to whether the storage transistor is turned on in a data reading stage.

Herein, in order to match the transfer direction of the current, among the first electrode S/D11 and the second electrode S/D12 of the storage transistor T1, one of them may be a source and the other of them may be a drain; and among the first electrode S/D21 and the second electrode S/D22 of the write transistor T2, one of them may be a source and the other of them may be a drain. Furthermore, in FIG. 3, both the storage transistor T1 and the write transistor T2 being the N-type transistors is taken as an example to describe, and the types of the transistors are not limited in practical applications.

In addition, the related description of the data read/write circuit in aforementioned some embodiments is combined, in the memory, the function of the first bit line BL1 is equivalent to the function of the aforementioned data signal line, the function of the second bit line BL2 is equivalent to the function of the aforementioned auxiliary signal line, the function of the first word line WL is equivalent to the function of the aforementioned first control signal line, and the function of the second word line WWL is equivalent to the function of the aforementioned second control signal line. The structures and usages of the first bit line BL1, the second bit line BL2, the first word line WL, and the second word line WWL of the memory may be performed correspondingly with reference to the data read/write circuit in the aforementioned embodiments, which will not be described in detail herein.

Some embodiments of the present disclosure also provide a method for driving a memory, for driving the aforementioned memory. With reference to FIG. 3, FIG. 6, FIG. 7 and FIG. 8, the method includes the following operations.

In a pre-charging stage tW1, the first bit line BL1 supplies the first reference voltage V1 to the first electrode S/D11 of the storage transistor T1. The second bit line BL2 supplies the first reference voltage V1 to both the second electrode S/D12 of the storage transistor T1 and the second electrode S/D22 of the write transistor T1. The first word line WL applies the first write control voltage VCW1 to the first gate G1. The second word line WWL applies the third write control voltage VCW3 to the second gate G2 and controls the write transistor T2 to be turned on, to pre-charge the storage node SN. The first reference voltage V1 is greater than a sum of a maximum data voltage to be written into the memory cell U and a threshold voltage VTH of the storage transistor T1.

In a data writing stage tW2, the second bit line BL2 is floated, and the first bit line BL1 supplies the data voltage Vdata to the first electrode S/D11 of the storage transistor T1. The storage transistor T1 is turned on; and the storage node SN is discharged to be in a stable state to write data data corresponding to the data voltage.

In a data reading stage tR, the second word line WWL applies the second turn-off control voltage VCG2 to the second gate G2, and the write transistor T2 is in the off state. The first word line WL applies the read control voltage VCR to the first gate G1. The second bit line BL2 supplies the second reference voltage V2 to both the second electrode S/D12 of the storage transistor T1 and the second electrode S/D22 of the write transistor T2. The first bit line BL1 reads the data written into the storage node SN in response to whether the storage transistor T1 is turned on.

In some embodiments, with reference to FIG. 7, the method further includes: in the data retention stage tW3, a voltage of the first bit line BL1 is pulled up to the first reference voltage V1, the write transistor T2 is turned off after the voltage of the first bit line BL1 is the first reference voltage V1, and then a voltage of the second bit line BL2 is pulled up to the first reference voltage V1.

In addition, with reference to FIG. 7, after the write transistor T2 is turned off, the method further includes: the first word line WL applies a first turn-off control voltage VCG1 to the first gate G1.

Exemplarily, the first turn-off control voltage VCG1 is the same as the second turn-off control voltage VCG2.

Exemplarily, both the storage transistor T1 and the write transistor T2 are the N-type transistors. Accordingly, both the first write control voltage VCW1 and the second write control voltage VCW2 are the high-level voltages. Both the first turn-off control voltage VCG1 and the second turn-off control voltage VCG2 are the low-level voltages. Furthermore, the first write control voltage VCW1 may be less than the second write control voltage VCW2, and the first write control voltage VCW1 may be reasonably set according to the requirements.

In some examples, with continued reference to FIG. 7, in the data retention stage tW3, after the write transistor T2 is turned off, the voltage of the second bit line BL2 is firstly pulled up to the first reference voltage V1, or the first turn-off control voltage VCG1 is firstly applied to the first gate G1 through the first word line WL. Alternatively, both the operations of the pulling up and the applying are performed, which also is allowed.

In other embodiment, with reference to FIG. 8, the method further includes: in the data retention stage tW3, the first word line WL first applies the first turn-off control voltage VCG1 to the first gate G1, and the voltage of the first bit line BL1 is pulled up to the first reference voltage V1; and then the write transistor T2 is turned off, and the voltage of the second bit line BL2 is pulled up to the first reference voltage V1.

Herein, it is to be understood that the turn-off of the write transistor T2 may be controlled by a second turn-off control voltage VCG2 applied by the second word line WWL to the second gate G2.

It is worth mentioning that, in some embodiments, with reference to FIG. 6, FIG. 7, and FIG. 8, the method further includes: in the first standby stage tD1 preceding the pre-charging stage tW1 and a second standby stage tD2 following the data retention stage tW3 and preceding the data reading stage tR, the first word line WL applies the first turn-off control voltage VCG1 to the first gate G1, the second word line WWL applies the second turn-off control voltage VCG2 to the second gate G2, the first bit line BL1 supplies the first reference voltage V1 to the first electrode S/D11 of the storage transistor T1, and the second bit line BL2 supplies the first reference voltage V1 to both the second electrode S/D12 of the storage transistor T1 and the second electrode S/D22 of the write transistor T2.

The technical principles of the driving method mentioned in the aforementioned some embodiments can be adaptively understood with reference to the technical principles of the aforementioned method for data read/write, which will not be described in detail herein.

Some embodiments of the present disclosure also provide an electronic device, e.g., a device having a data storage function, such as, a data storage device, a photocopier, a network device, a household appliance, an instrument, a mobile phone, a computer, and the like. The electronic device may include a housing and a circuit board disposed within the housing, a memory or a data read/write circuit integrated on the circuit board. The structure of the memory or the data read/write circuit can refer to the related description in aforementioned some embodiments. The electronic device may also include other necessary elements or components, which is not limited in the embodiments of the present disclosure.

In some embodiments, the memory may be coupled to an external control device, such as, a processor or an actuator. When the processor is coupled to the memory, the processor is able to control the read/write operation of the memory.

In some embodiments, the memory is three-dimensional dynamic random access memory.

Various technical features of the foregoing embodiments may be randomly combined. For conciseness of description, not all possible combinations of various technical features in the foregoing embodiments are described. However, as long as the combinations of these technical features do not contradict, they should be regarded as falling within the scope of the present specification.

The foregoing embodiments describe only a few implementations of the present disclosure, and the descriptions are specific and detailed, but cannot therefore be construed as limiting of the patent scope of the present disclosure. It should be noted that those of ordinary skill in the art may further make variations and improvements without departing from the conception of the present disclosure, and these all fall within the protection scope of the present disclosure. Therefore, the patent protection scope of the present disclosure should be subject to the appended claims.

1. A method for data read/write applied to a memory cell, wherein the memory cell is configured to store data and comprises a storage transistor and a write transistor that are connected with each other; a data read/write cycle of the memory cell comprises: a pre-charging stage and a data writing stage; and the method for data read/write comprises:
in the pre-charging stage, supplying, by a data signal line, a first reference voltage to the storage transistor; supplying, by an auxiliary signal line, the first reference voltage to both the storage transistor and the write transistor; and turning on the write transistor to pre-charge a storage node between the write transistor and the storage transistor, wherein a sum of a maximum data voltage corresponding to the data and a threshold voltage of the storage transistor is a reference voltage, and the first reference voltage is greater than the reference voltage; and
in the data writing stage, in response to a write command, floating the auxiliary signal line, and supplying, by the data signal line, a data voltage to the storage transistor; and turning on the storage transistor, and discharging the storage node to be in a stable state to write the data corresponding to the data voltage.

2. The method for data read/write of claim 1, wherein the data read/write cycle further comprises: a data retention stage following the data writing stage; and the method for data read/write further comprises:
in the data retention stage, pulling up a voltage of the data signal line to the first reference voltage, turning off the write transistor after the voltage of the data signal line is the first reference voltage, and then pulling up a voltage of the auxiliary signal line to the first reference voltage;
wherein after turning off the write transistor, the method for data read/write further comprises: applying a first turn-off control voltage to the storage transistor.

3. The method for data read/write of claim 1, wherein the data read/write cycle further comprises: a data retention stage following the data writing stage; and the method for data read/write further comprises:
in the data retention stage, turning off firstly the storage transistor and pulling up a voltage of the data signal line to the first reference voltage; and then turning off the write transistor and pulling up a voltage of the auxiliary signal line to the first reference voltage.

4. The method for data read/write of claim 1, wherein the data read/write cycle further comprises: a data reading stage; and the method for data read/write further comprises:
in the data reading stage, in response to a read command, applying a read control voltage to the storage transistor and supplying, by the auxiliary signal line, a second reference voltage to both the storage transistor and the write transistor; wherein the data signal line is further configured to read data in response to whether the storage transistor is turned on.

5. The method for data read/write of claim 1, wherein data written into the storage node comprises “1” or “0”; and in the data reading stage, the storage transistor is in a on state when the data stored in the storage node is “1”, and the storage transistor is in an off state when the data stored in the storage node is “0”.

6. The method for data read/write of claim 1, wherein the data read/write cycle further comprises: a standby stage preceding the pre-charging stage and/or preceding the data reading stage; and the method for data read/write further comprises:
in the standby stage, the storage transistor and the write transistor are in an off state, supplying, by the data signal line, the first reference voltage to the storage transistor, and supplying, by the auxiliary signal line, the first reference voltage to both the storage transistor and the write transistor.

7. The method for data reading/writing of claim 6, wherein the data reading/writing cycle further comprises: a data retention stage following the data writing stage; and the data reading stage is following the data retention stage;
the standby stage comprises a first standby stage preceding the pre-charging stage, and a second standby stage following the data retention stage and preceding the data reading stage.

8. A data read/write circuit, comprising:
a memory cell, configured to store data and comprising a storage transistor and a write transistor that are connected with each other;
a data signal line, connected to the storage transistor and configured to: supply a first reference voltage to the storage transistor in a standby stage and a pre-charging stage, write data into the storage transistor in a data writing stage, and read data in response to whether the storage transistor is turned on in a data reading stage; and
an auxiliary signal line, connected to the storage transistor and the write transistor, and configured to: supply the first reference voltage to both the storage transistor and the write transistor in the standby stage and the pre-charging stage, be floated in the data writing stage, and supply a second reference voltage to both the storage transistor and the write transistor in the data reading stage,
wherein a sum of a maximum data voltage corresponding to the data and a threshold voltage of the storage transistor is a reference voltage; and the first reference voltage is greater than the reference voltage.

9. The data read/write circuit of claim 8, further comprising:
a first control signal line, connected to the storage transistor and configured to: control the storage transistor to be turned off in the standby stage, apply a first write control voltage to the storage transistor in the pre-charging stage and the data writing stage, and apply a read control voltage to the storage transistor in the data reading stage; and
a second control signal line, connected to the write transistor and configured to: control the write transistor to be turned off in the standby stage and the data reading stage, and control the write transistor to be turned on in the pre-charging stage and the data writing stage.

10. The data read/write circuit of claim 9, wherein
the data signal line is further configured to: supply the first reference voltage to the storage transistor in a data retention stage;
the second control signal line is further configured to: control the write transistor to be turned off after a voltage of the data signal line is the first reference voltage in the data retention stage; and
the auxiliary signal line is further configured to: supply the first reference voltage to both the storage transistor and the write transistor after the write transistor is turned off in the data retention stage,
wherein the first control signal line is further configured to: apply a first turn-off control voltage to the storage transistor after the write transistor is turned off in the data retention stage.

11. The data read/write circuit of claim 9, wherein
the first control signal line is further configured to: control the storage transistor to be turned off earlier than the write transistor in a data retention stage;
the data signal line is further configured to: supply the first reference voltage to the storage transistor after the storage transistor is turned off in the data retention stage;
the second control signal line is further configured to: control the write transistor to be turned off after the data signal line supplies the first reference voltage in the data retention stage; and
the auxiliary signal line is further configured to: supply the first reference voltage to both the storage transistor and the write transistor after the write transistor is turned off in the data retention stage.

12. The data read/write circuit of claim 9, wherein the storage transistor comprises: a storage gate, a first gate, a first electrode, and a second electrode; and the write transistor comprises: a second gate, a first electrode, and a second electrode; wherein
the first gate is connected to the first control signal line;
the second gate is connected to the second control signal line;
the first electrode of the storage transistor is connected to the data signal line;
the first electrode of the write transistor is connected to the storage gate, and an intersection point where the first electrode of the write transistor is connected to the storage gate is a storage node; and
the second electrode of the storage transistor and the second electrode of the write transistor are respectively connected to the auxiliary signal line.

13. The data read/write circuit of claim 9, wherein there are a plurality of memory cells; the plurality of the memory cells are arranged in a row in a first direction and arranged in a column in a second direction; and the first direction intersects with the second direction;
wherein a column of the memory cells share one data signal line and one auxiliary signal line; and
a row of the memory cells share one first control signal line and one second control signal line.

14. The data read/write circuit of claim 8, further comprising:
a first reference voltage terminal, correspondingly connected to the data signal line through a first gating circuit and correspondingly connected to the auxiliary signal line through a second gating circuit, wherein the first reference voltage terminal is configured to supply the first reference voltage; the first gating circuit is configured to: selectively connect the first reference voltage terminal to the data signal line in the standby stage and the pre-charging stage; and the second gating circuit is configured to: selectively connect the first reference voltage terminal to the auxiliary signal line in the standby stage and the pre-charging stage; and
a second reference voltage terminal, correspondingly connected to the auxiliary signal line through a third gating circuit, wherein the second reference voltage terminal is configured to supply the second reference voltage; and the third gating circuit is configured to: selectively connect the second reference voltage terminal to the auxiliary signal line in the data reading stage.

15. A memory comprising: at least one memory cell, and a first bit line, a second bit line, a first word line, and a second word line that are correspondingly connected to the memory cell;
wherein the memory cell comprises: a storage transistor and a write transistor; the storage transistor comprises a storage gate, a first gate, a first electrode, and a second electrode; and the write transistor comprises a second gate, a first electrode, and a second electrode;
the storage gate is connected to the first electrode of the write transistor, and an intersection point where the storage gate is connected to the first electrode of the write transistor is a storage node;
the first word line is connected to the first gate, and the second word line is connected to the second gate; and
the first bit line is connected to the first electrode of the storage transistor, and the second bit line is connected to both the second electrode of the storage transistor and the second electrode of the write transistor,
wherein the first bit line is configured to: supply a first reference voltage to the first electrode of the storage transistor in a pre-charging stage, supply a data voltage of data to be written into the storage transistor in a data writing stage, and read data written into the memory node in response to whether the storage transistor is turned on in a data reading stage; and
the second bit line is configured to: supply the first reference voltage to both the second electrode of the storage transistor and the second electrode of the write transistor in the pre-charging stage, be floated in the data writing stage, and supply a second reference voltage to both the storage transistor and the write transistor in the data reading stage,
wherein the first reference voltage is greater than a sum of a maximum data voltage to be written into the memory cell and a threshold voltage of the storage transistor.

16. A method for driving a memory, applied to the memory of claim 15; the method comprising:
in a pre-charging stage, supplying, by the first bit line, the first reference voltage to the first electrode of the storage transistor and supplying, by the second bit line, the first reference voltage to both the second electrode of the storage transistor and the second electrode of the write transistor; applying, by the first word line, a first write control voltage to the first gate and applying, by the second word line, a second write control voltage to the second gate to control the write transistor to be turned on to pre-charge the storage node, wherein the first reference voltage is greater than a sum of a maximum data voltage to be written into the memory cell and a threshold voltage of the storage transistor;
in a data writing stage, floating the second bit line and supplying, by the first bit line, a data voltage to the first electrode of the storage transistor; turning on the storage transistor, discharging the storage node to be in a stable state to write data corresponding to the data voltage; and
in a data reading stage, applying, by the second word line, a second turn-off control voltage to the second gate, the write transistor being in an off state; applying, by the first word line, a read control voltage to the first gate; supplying, by the second bit line, a second reference voltage to both the second electrode of the storage transistor and the second electrode of the write transistor; and reading, by the first bit line, the data written into the storage node in response to whether the storage transistor is turned on.

17. An electronic device comprising: the data read/write circuit of claim 8.

18. An electronic device comprising the memory of claim 15.

19. The method for data read/write of claim 2, wherein the data read/write cycle further comprises: a data retention stage following the data writing stage; and the method for data read/write further comprises:
in the data retention stage, turning off firstly the storage transistor and pulling up a voltage of the data signal line to the first reference voltage; and then turning off the write transistor and pulling up a voltage of the auxiliary signal line to the first reference voltage.

20. The method for data read/write of claim 2, wherein the data read/write cycle further comprises: a data reading stage; and the method for data read/write further comprises:
in the data reading stage, in response to a read command, applying a read control voltage to the storage transistor and supplying, by the auxiliary signal line, a second reference voltage to both the storage transistor and the write transistor; wherein the data signal line is further configured to read data in response to whether the storage transistor is turned on.
